(19) United States
(12) Patent Application Publication
(10) Pub. No.: US 2012/0001311 A1
(43) Pub. Date: Jan. 5, 2012

(54) PACKAGE FOR SEMICONDUCTOR DEVICE, AND METHOD OF MANUFACTURING THE SAME AND SEMICONDUCTOR DEVICE

(75) Inventors: Masanori Nishino, Kyoto (JP); Hiroshi Horiki, Kyoto (JP)

(73) Assignee: PANASONIC CORPORATION, Osaka (JP)

(21) Appl. No.: 13/165,478

(22) Filed: Jun. 21, 2011

(30) Foreign Application Priority Data
Jun. 22, 2010 (JP) 2010-141127
May 23, 2011 (JP) 2011-114259

(51) Int. Cl. H01L 23/495; H01L 21/60

(52) U.S. Cl. 257/676; 438/123; 257/E23.042; 257/E21.506

(57) ABSTRACT

In a package for a semiconductor device according to the present invention, steps 10 are provided at least on the sides of lead frames 1 and 2 at exposed portions in the opening of a resin part 3, thereby increasing adhesion between the lead frames 1 and 2 and resin and suppressing leakage of molding resin and intrusion of outside air or moisture from a gap between the lead frames 1 and 2 and the resin.

### FIELD OF THE INVENTION

The present invention relates to a semiconductor device in which molding resin is provided in a resin part forming the mounting region of a semiconductor element while holding lead frames, and a package used for the semiconductor device.

### BACKGROUND OF THE INVENTION

Referring to FIGS. 6A to 6C, the following will describe a package for a semiconductor device according to the related art.

FIGS. 6A to 6C are schematic drawings showing the configuration of the package for a semiconductor device according to the related art. FIG. 6A is a top view. FIG. 6B is a cross-sectional view taken along line X-X′ of FIG. 6A. FIG. 6C shows the configuration of a semiconductor device using the package for a semiconductor device according to the related art.

As shown in FIGS. 6A to 6C, the package for a semiconductor device according to the related art includes: a lead frame 21 including the mounting region of a semiconductor element on inner leads; a lead frame 22 including a connected region to the semiconductor device on inner leads; a resin part 23 that holds the lead frames 21 and 22 on the top surfaces of the lead frames and opens the mounting region of the semiconductor element; and resin 24 provided on the sides and undersides of the lead frames 21 and 22 to hold the lead frames 21 and 22.

The semiconductor device using the package for a semiconductor device is formed by mounting a semiconductor element 25 on the mounting region of the package for a semiconductor device, connecting the semiconductor element 25 and the connected region via a wire 26, and injecting molding resin 27 into the opening of the resin part 23 so as to mold the semiconductor element 25 and the wire 26.

### DISCLOSURE OF THE INVENTION

In the package for a semiconductor device according to the related art, unfortunately, adhesion may become insufficient between the lead frames 21 and 22 and the resin 24 or the resin part 23. For example, in the formation of the resin 24 or the resin part 23, thermal shrinkage may form a gap 28 between the lead frames 21 and 22 and the resin 24 in a cooling process after the injection of resin. Moreover, a stress such as an external force may form the gap 28 between the lead frames 21 and 22 and the resin 24. In the case where the gap 28 is formed between the lead frames 21 and 22 and the resin 24, the molding resin 27 leaks from the gap 28 during potting of the molding resin 27 in the formation of the semiconductor device. Thus the semiconductor device may have a poor appearance, the opening of the resin part 23 may contain an insufficient amount of the molding resin 27, or a leak of the molding resin 27 may adhere to an external terminal and cause faulty connection or faulty packaging. Moreover, outside air or moisture may enter the molding resin 27 from the gap 28 and generate air bubbles in the molding resin 27 or reduce the humidity resistance of the molding resin 27. Furthermore, the lead frames 21 and 22 may be unstably fixed, leading to a displacement of the mounted semiconductor element or faulty connection.

The present invention has been devised to solve the problems. An object of the present invention is to suppress leakage of molding resin and intrusion of outside air or moisture from a gap between lead frames and resin.

In order to attain the object, a package for a semiconductor device according to the present invention includes: at least one first lead frame having an element mounting region on the major surface; at least one second lead frame that has a connected region on the major surface and is electrically isolated; a resin part formed on the major surfaces of the first and second lead frames so as to open the element mounting region and the connected region; a step formed at least on each side of the first and second lead frames exposed from the resin part in the opening of the resin part; and holding resin provided at least partially on each side of the first and second lead frames with respect to the major surfaces and in a gap between the first and second lead frames.

Preferably, the step is formed on each of the major surfaces of the first and second lead frames.

Preferably, the step is formed on each of the back sides of the first and second lead frames with respect to the major surfaces of the lead frames.

Preferably, the step is formed on each of the major surfaces of the first and second lead frames and each of the back sides of the lead frames with respect to the major surfaces.

Preferably, the step includes discontinuously formed steps.

Preferably, the step includes a continuously formed step.

The holding resin may be also provided on the back sides of the lead frames with respect to the major surfaces.

The holding resin exposed from the gap between the first and second lead frames in the opening of the resin part may have a surface including asperities.

The asperities may include projections.

The asperities may include recesses.

The asperities may include at least one groove.

The resin part may be a reflector and the package may be a package for an optical semiconductor device.

A method of manufacturing a package for a semiconductor device according to the present invention, the method including: a lead frame processing step of forming a step on a side of a lead frame with respect to the major surface; a die step of placing the lead frame in a die; and a resin injecting step of injecting resin into the die to form a resin part that opens an element mounting region and holding resin that holds the lead frame, wherein the step is formed at least on the side of the lead frame exposed from the resin part in the opening of the resin part.

The step may be formed by coining.

A semiconductor device according to the present invention includes: the package for a semiconductor device; a semiconductor element mounted on the element mounting region; a conductive material electrically connecting the semiconductor element and the connected region; and molding resin that molds the inside of the opening of the resin part.

Moreover, a semiconductor device including: the package for a semiconductor device; an optical semiconductor element mounted on the element mounting region; a conductive material electrically connecting the optical semiconductor element and the connected region; and translucent resin that molds the inside of the opening of the reflector, wherein the semiconductor device may be an optical semiconductor device.

### BRIEF DESCRIPTION OF THE DRAWINGS

FIG. 1A shows the configuration of a package for a semiconductor device according to a first embodiment;

FIG. 1B shows the configuration of the package for a semiconductor device according to the first embodiment;

FIG. 1C shows the configuration of the package for a semiconductor device according to the first embodiment;

FIG. 2A is a process sectional view showing a manufacturing process of a package for a semiconductor device according to the present invention;

FIG. 2B is a process sectional view showing the manufacturing process of the package for a semiconductor device according to the present invention;

FIG. 2C is a process sectional view showing the manufacturing process of the package for a semiconductor device according to the present invention;

FIG. 2D is a process sectional view showing the manufacturing process of the package for a semiconductor device according to the present invention;

FIG. 3A shows the configuration of a package for a semiconductor device according to a second embodiment;

FIG. 3B shows the configuration of the package for a semiconductor device according to the second embodiment;

FIG. 3C shows the configuration of the package for a semiconductor device according to the second embodiment;

FIG. 3D shows the configuration of the package for a semiconductor device according to the second embodiment;

FIG. 4A shows the configuration of resin between lead frames in a package for a semiconductor device according to a third embodiment;

FIG. 4B shows the configuration of the resin between the lead frames in the package for a semiconductor device according to the third embodiment;

FIG. 4C shows the configuration of the resin between the lead frames in the package for a semiconductor device according to the third embodiment;

FIG. 5A shows the configuration of a semiconductor device according to a fourth embodiment;

FIG. 5B shows the configuration of the semiconductor device according to the fourth embodiment;

FIG. 6A is a schematic drawing showing the configuration of a package for a semiconductor device according to the related art;

FIG. 6B is a schematic drawing showing the configuration of the package for a semiconductor device according to the related art; and

FIG. 6C is a schematic drawing showing the configuration of the package for a semiconductor device according to the related art.

### DESCRIPTION OF THE EMBODIMENTS

### First Embodiment

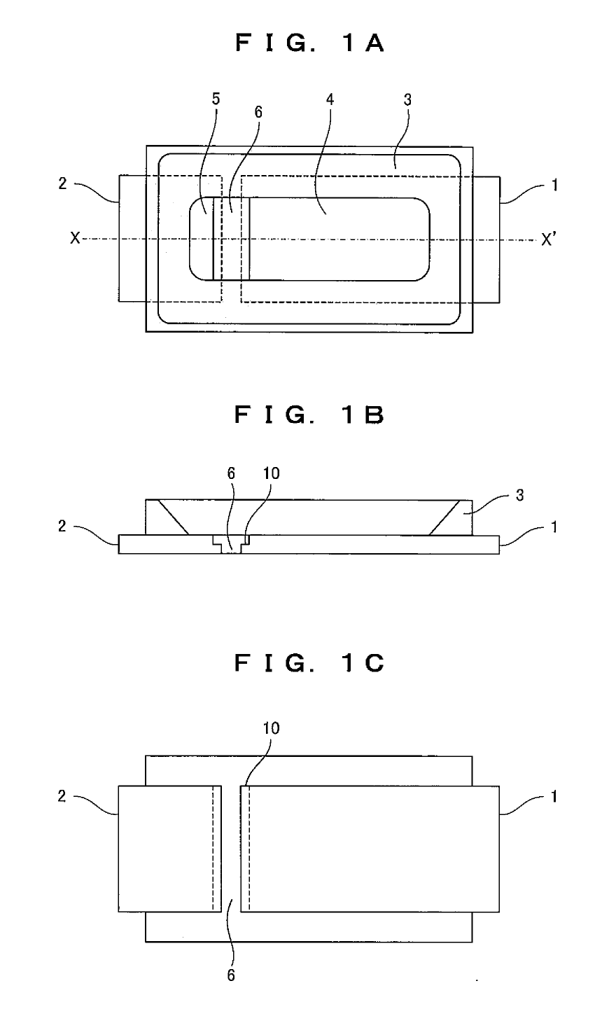

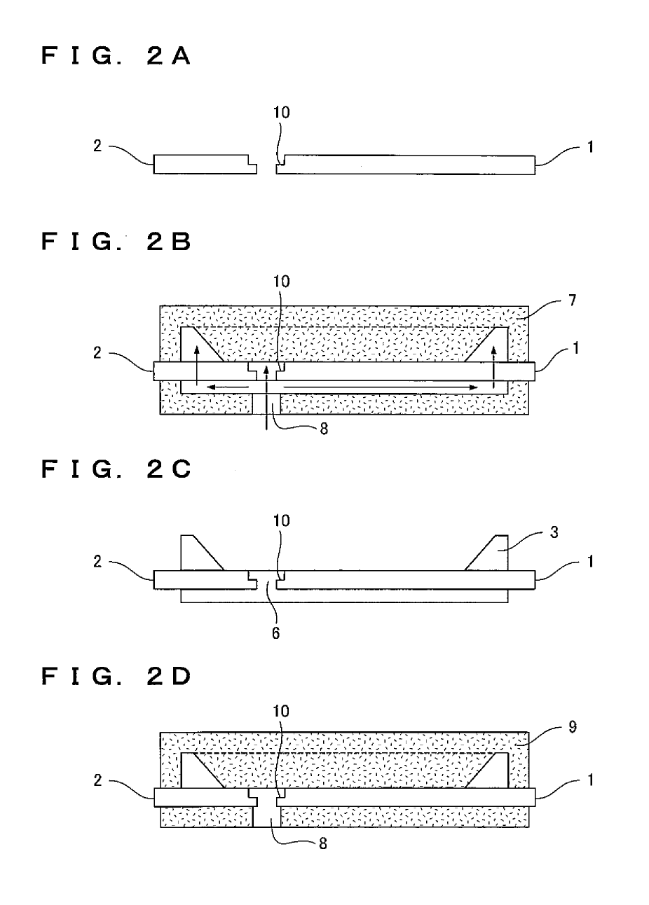

First, referring to FIGS. 1A to 1C and 2A to 2D, the following will describe the configuration of a package for a semiconductor device and a method of manufacturing the same according to a first embodiment.

FIGS. 1A to 1C show the configuration of the package for a semiconductor device according to the first embodiment. FIG. 1A is a top view, FIG. 1B is a cross-sectional view taken along line X-X′ of FIG. 1A, and FIG. 1C is a back view. FIGS. 2A to 2D are process sectional views showing the manufacturing process of the package for a semiconductor device according to the present invention.

In FIGS. 1A to 1C, reference numeral 1 denotes a lead frame including a mounting region 4 of a semiconductor element on inner leads, reference numeral 2 denotes a lead frame including a connected region 5 to a semiconductor device on the inner leads, reference numeral 3 denotes a resin part that is formed on the lead frame 1 and the lead frame 2 to hold the lead frames and surrounds the mounting region 4 and the connected region to protect the regions, reference numeral 6 denotes holding resin that is provided in a gap between the lead frames 1 and 2, on the sides of the lead frames, and optionally on the back sides of the lead frames to hold the lead frames 1 and 2, and reference numeral 10 denotes steps formed at least at portions exposed from the resin part 3 in the opening of the resin part 3, on the opposed sides of the lead frames 1 and 2. The package for a semiconductor device according to the present invention includes the steps 10 on the sides of the lead frames 1 and 2 exposed from the resin part 3 in the opening, the step 10 forming a thin portion on the lead frame, so that adhesion increases between the lead frames 1 and 2 and the holding resin 6 and the occurrence of gaps can be suppressed.

In FIGS. 1A to 1C, the package for a semiconductor device with two terminals includes the single lead frame 2. Multiple lead frames 2 may be provided. In this case, the steps 10 are preferably formed not only on the opposed sides of the lead frames 1 and 2 at least in a region exposed from the resin part 3 in the opening but also on the opposed sides of the adjacent lead frames 2.

Referring to FIGS. 2A to 2D, the following will describe the method of manufacturing the package for a semiconductor device according to the present invention.

First, as shown in FIG. 2A, the steps 10 are formed at least at the portions exposed from the resin part 3 in the opening, on the opposed sides of the lead frames 1 and 2. The steps 10 may be formed by any methods including coining and etching. Particularly, coining by press working can achieve high accuracy and high mass productivity.

Next, as shown in FIG. 2B, the lead frames 1 and 2 are placed in a die 7 for forming the resin part 3. In this state, resin is injected from a resin inlet 8 of the die 7. The injected resin fills the space of the die 7 to form the resin part 3 and the holding resin 6.

Finally, as shown in FIG. 2C, the die 7 is removed after the resin is cured. Thus the package for a semiconductor device is completed in which the resin part 3 is provided on the lead frames 1 and 2 and the lead frames 1 and 2 are held at least by the resin part 3, the resin on the sides of the lead frames 1 and 2, and the holding resin 6 in the gap between the lead frames 1 and 2.

The steps are formed at least at the portions exposed from the resin part 3 in the opening, on the opposed sides of the lead frames 1 and 2, so that adhesion between the lead frames 1 and 2 and the holding resin 6 increases at least at the injection point of the molding resin and the occurrence of gaps can be suppressed. Thus when the molding resin is injected into the opening of the resin part 3, it is possible to suppress leakage of the molding resin and intrusion of outside air or moisture into the opening.

In this explanation of the manufacturing method, the holding resin 6 is also applied to the backsides of the lead frames 1 and 2 with respect to the element mounting surface. As long as the lead frames 1 and 2 can be sufficiently held, the backsides of the lead frames 1 and 2 may be uncoated with the holding resin 6 to reduce the thickness of the package for a semiconductor device as shown in FIGS. 1A to 1C.

In this case, the die 7 of FIG. 2B is replaced with a die 9 of FIG. 2D, so that a package for a semiconductor device can be formed with the backside uncoated with holding resin.

### Second Embodiment

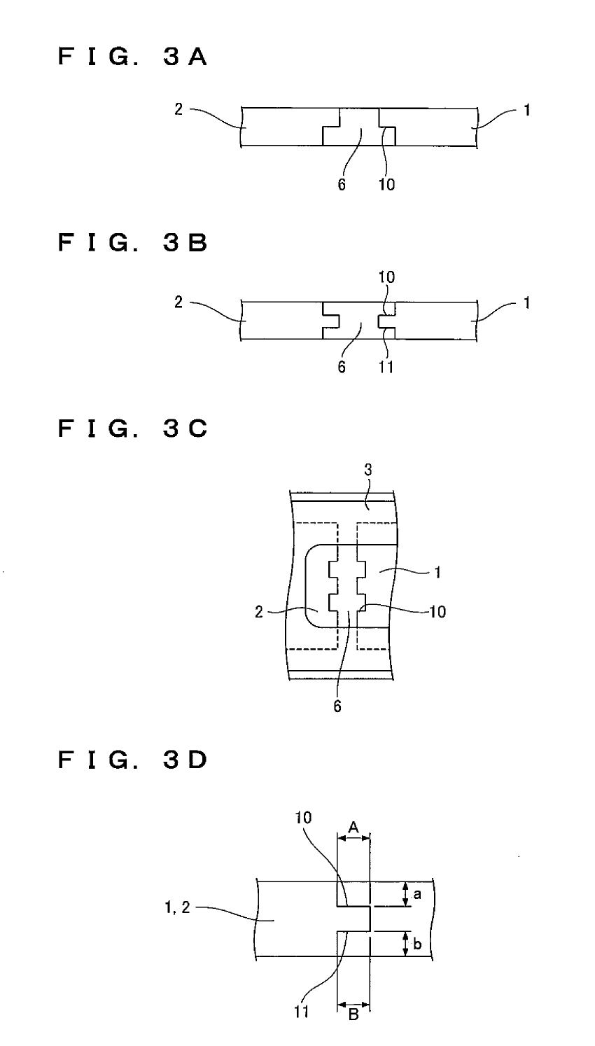

Referring to FIGS. 3A to 3D, the following will describe the configurations of a package for a semiconductor device according to a second embodiment.

FIGS. 3A to 3D show the configurations of the package for a semiconductor device and structural examples of steps according to the second embodiment.

In the first embodiment, the steps 10 are provided on the top surfaces of the lead frames 1 and 2, that is, on the mounting surface of a semiconductor element to form thin portions on the back sides of the lead frames with respect to the top surfaces, whereas as shown in FIG. 3A, steps 11 may be provided on the back sides of lead frames 1 and 2 with respect to the top surfaces of the lead frames, at least at portions exposed from a resin part 3 in the opening of the resin part 3 on the opposed sides of the lead frames 1 and 2. Like the steps 10 provided on the top surfaces, the steps 11 provided on the back sides can improve adhesion between the lead frames 1 and 2 and holding resin 6 at least at the injection point of molding resin and suppress the occurrence of gaps. Thus when the molding resin is injected into the opening of the resin part 3, it is possible to suppress leakage of the molding resin and intrusion of outside air or moisture into the opening.

Since the holding resin 6 also fills the steps 11 on the back sides of the lead frames 1 and 2, the anchor effect can improve the holding power of the holding resin 6 on the lead frames 1 and 2 and thus reduce the need for the holding resin 6 formed on the back sides of the lead frames 1 and 2. In this case, the holding resin 6 is easily formed in a gap between the lead frames 1 and 2 and on the sides of the lead frames 1 and 2 except for the back sides of the lead frames 1 and 2, so that the package for a semiconductor device can be easily reduced in thickness.

As shown in FIG. 3B, the steps 10 and the steps 11 may be simultaneously formed on the front and back sides of the lead frames 1 and 2. With this configuration, adhesion between the lead frames 1 and 2 and the holding resin 6 can be further increased at least at the injection point of the molding resin and the occurrence of gaps can be suppressed, thereby more reliably suppressing leakage of the molding resin and intrusion of outside air or moisture. Particularly, blocking of moisture can prevent the package from being damaged by breakage of the molding resin or the resin part 3 at the expansion and contraction of moisture in the molding resin. Furthermore, the anchor effect improves and the holding power of the holding resin 6 further increases on the lead frames 1 and 2, thereby more easily eliminating the need for the holding resin 6 on the back sides of the lead frames 1 and 2. Moreover, the lead frames can be reliably fixed with the resin, improving the accuracy of positioning of a semiconductor element with stable connection.

In the first embodiment, the steps 10 are continuously formed in parallel with the opposed sides of the lead frames 1 and 2, whereas in the second embodiment, as shown in FIG. 3C, the steps 10 and 11 or the steps 10 or 11 may be discontinuously arranged in parallel with the opposed sides of the lead frames 1 and 2. Since the steps 10 or 11 are discontinuously formed, the holding resin 6 is applied between the steps and the adhesion and holding power are increased.

As shown in FIG. 3D, the step 10 has width A and depth a and the step 11 has width B and depth b. These dimensions are desirably determined by comparing the following effects: in the case where the widths A and B are increased, a larger amount of holding resin is injected into the steps 10 and 11 and a contact area increases between the lead frames 1 and 2 and the holding resin, leading to larger adhesion between the lead frames 1 and 2 and the holding resin. The larger the width A, the smaller the mounting region or the connected region. The larger the width B, the smaller the exposed areas of the lead frames 1 and 2, resulting in lower efficiency of heat dissipation even if the holding resin is not formed on the back sides of the lead frames 1 and 2. In the case where the depths a and b are increased, a larger amount of the holding resin is injected into the steps 10 and 11 with a larger contact area between the lead frames 1 and 2 and the holding resin. Thus adhesion increases between the lead frames 1 and 2 and the holding resin and the resin easily passes through the steps 10 and 11 with higher resin injection efficiency. In the case where the lead frames 1 and 2 are extremely reduced in thickness, the lead frames 1 and 2 have insufficient strength.

The manufacturing process of the package for a semiconductor device is similar to that of the explanation of the first embodiment illustrated in FIGS. 2A to 2D.

The packages for a semiconductor device according to the first and second embodiments can be used as packages for an optical semiconductor device by replacing the resin part 3 on the top surfaces of the lead frames 1 and 2 with a reflector. In this case, it is preferable that the reflector is made of resin having a high light reflectance or a reflector surface on an element mounting surface is coated with a material having a high light reflectance, improving luminous efficiency. Moreover, the reflector surface on the element mounting surface is preferably inclined to the element mounting surface to improve the luminous efficiency.

### Third Embodiment

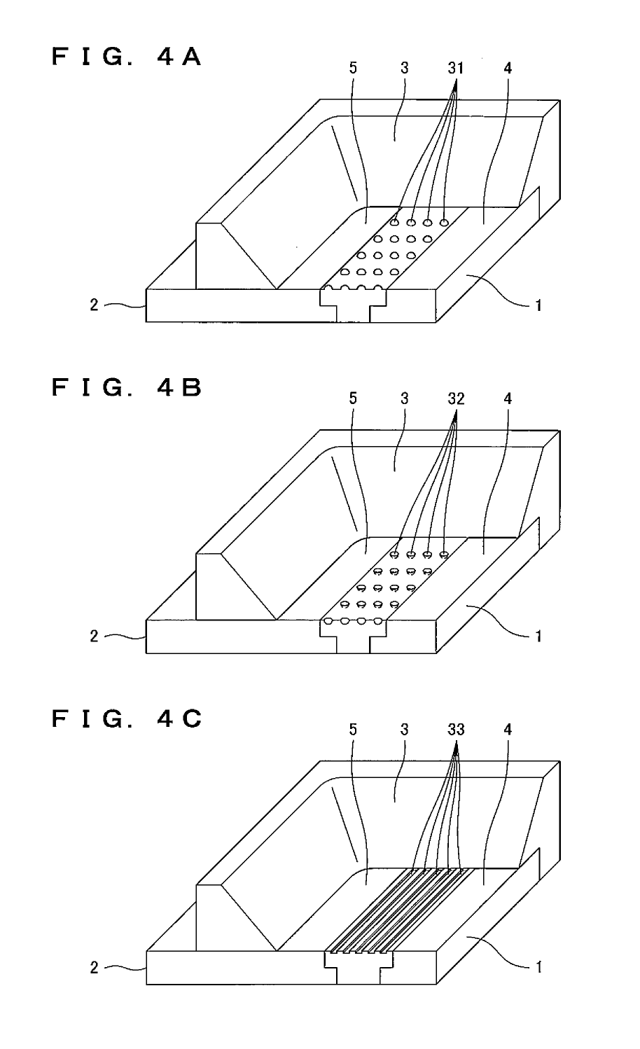

Referring to FIGS. 4A to 4C, the following will describe the configurations of a package for a semiconductor device according to a third embodiment.

FIGS. 4A to 4C show the configurations of resin between lead frames of the package for a semiconductor device according to the third embodiment. FIG. 4A is a perspective view illustrating a main part including projecting portions as asperities. FIG. 4B is a perspective view illustrating the main part including recessed portions as asperities. FIG. 4C is a perspective view illustrating the main part including grooves as asperities.

A feature of the package for a semiconductor device according to the third embodiment is the formation of asperities on an exposed surface between the lead frames 1 and 2 in the holding resin 6 of the package for a semiconductor device according to the first or second embodiment.

As shown in FIGS. 4A to 4C, a resin part 3 surrounds a mounting region 4 on the surface of the lead frame 1 and a connected region 5 on the surface of the lead frame 2. The holding resin 6 is formed partially around the lead frames 1 and 2 and between the lead frames 1 and 2. The holding resin 6 is exposed from a surface on which the mounting region 4 and the connected region 5 are formed, between the lead frames 1 and 2 in the opening of the resin part 3. Asperities are formed at least on the surface of a region where the holding resin 6 is exposed between the lead frames 1 and 2. The asperities are formed beforehand on the exposed surface of the holding resin 6, so that a semiconductor device can be mounted in the package for a semiconductor device while suppressing leakage of molding resin and intrusion of outside air or moisture from a gap between the lead frames and the resin. Furthermore, in the case where a region surrounded by the resin part 3 is molded with the molding resin, the asperities can increase a contact area between the holding resin 6 and the molding resin and adhesion between the holding resin 6 and the molding resin, thereby preventing the molding resin from peeling off and reliably molding the region with the molding resin.

The asperities formed on the surface of the holding resin 6 may be specifically shaped like, for example, protrusions 31 (FIG. 4A), recesses 32 (FIG. 4B), or at least one groove 33 formed in any directions (FIG. 4C) including a direction parallel to a side of the lead frame 1, the side being opposed to the lead frame 2, a direction orthogonal to the side of the lead frame 1, and combined directions. Alternatively, the protrusions 31, the recesses 32, and the groove 33 may be combined. The protrusions 31 or the recesses 32 may have any shapes including a spherical surface, a prism, and a pyramid, or these shapes may be combined. The protrusions 31 or the recesses 32 may have any sizes and may be uniform or varied in size. Moreover, the protrusions 31 or the recesses 32 may be regularly or irregularly arranged. The grooves 33 may have any sizes and vary in length, width, and depth. FIGS. 4A to 4C show the provision of the asperities on the exposed holding resin 6 of the package for a semiconductor device according to the first embodiment. The holding resin 6 exposed between the lead frames 1 and 2 with various shapes of the steps according to the second embodiment may include the asperities of FIGS. 4A to 4C.

The die 7 of FIG. 2B or the die 9 of FIG. 2D is shaped to form the asperities, so that the asperities can be formed concurrently with the formation of the resin part 3 and the holding resin 6. The asperities may be formed by processing such as cutting and etching after the formation of the holding resin 6.

### Fourth Embodiment

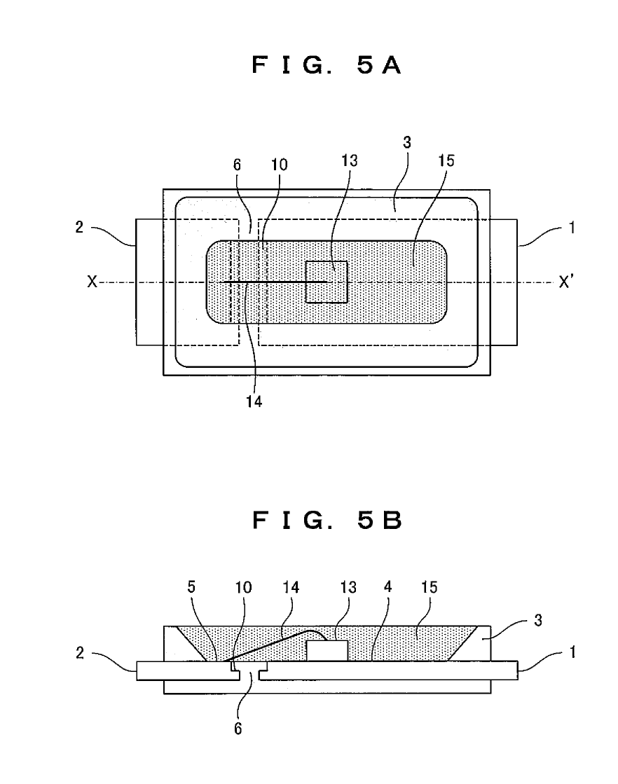

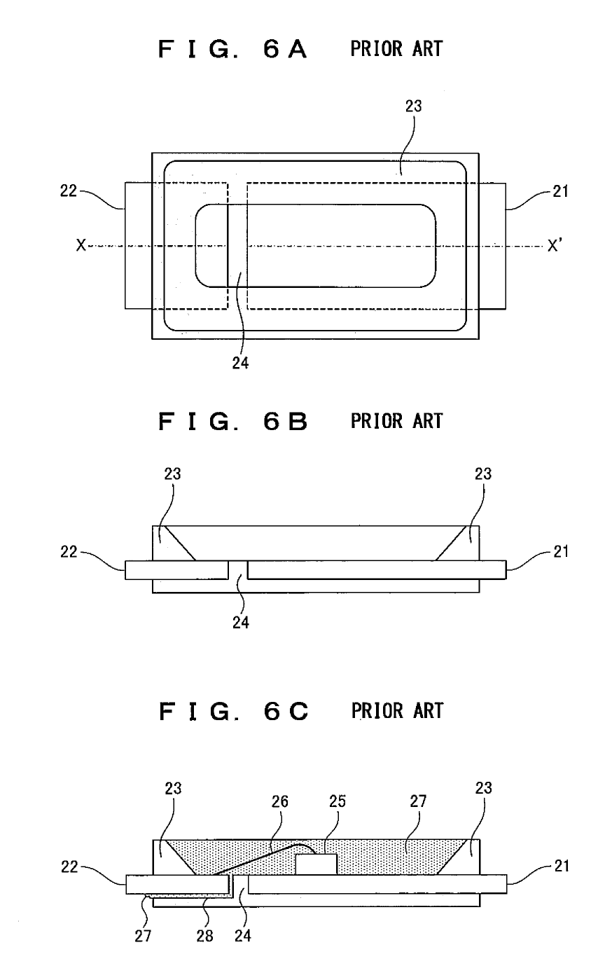

Referring to FIGS. 5A and 5B, the following will describe the configuration of a semiconductor device using the packages for a semiconductor device according to the first to third embodiments.

FIGS. 5A and 5B show the configuration of the semiconductor device according to a third embodiment. FIG. 5A is a top view and FIG. 5B is a cross-sectional view taken along line X-XT of FIG. 5A.

As shown in FIGS. 5A and 5B, the semiconductor device of the third embodiment is formed by fixing a semiconductor element 13 with, for example, conductive adhesive on the mounting region 4 in the packages for a semiconductor device according to the first to third embodiments, electrically connecting the semiconductor element 13 and the connected region 5 via conductive materials including a wire 14, and forming molding resin 15 in a region surrounded by the resin part 3 and the lead frames 1 and 2 such that the semiconductor element 13 and the wire 14 are molded with the molding resin 15. In the case where the back sides of the lead frames 1 and 2 are uncoated with resin in the package for a semiconductor device, heat generated in an operation of the semiconductor element 13 can be quickly released. Additionally, the semiconductor device can be reduced in thickness.

An optical semiconductor device may be formed using the package for an optical semiconductor device, an optical semiconductor element serving as the semiconductor element 13, and translucent resin serving as the molding resin 15.

What is claimed is:

1. A package for a semiconductor device, comprising:
at least one first lead frame having an element mounting region on a major surface;
at least one second lead frame that has a connected region on a major surface and is electrically isolated;
a resin part formed on the major surfaces of the first and second lead frames so as to open the element mounting region and the connected region;
a step formed at least on each side of the first and second lead frames exposed from the resin part in an opening of the resin part; and
holding resin provided at least partially on each side of the first and second lead frames with respect to the major surfaces and in a gap between the first and second lead frames.

2. The package for a semiconductor device according to claim 1, wherein the step is formed on each of the major surfaces of the first and second lead frames.

3. The package for a semiconductor device according to claim 1, wherein the step is formed on each of back sides of the first and second lead frames with respect to the major surfaces of the lead frames.

4. The package for a semiconductor device according to claim 1, wherein the step is formed on each of the major surfaces of the first and second lead frames and each of back sides of the lead frames with respect to the major surfaces.

5. The package for a semiconductor device according to claim 1, wherein the step includes discontinuously formed steps.

6. The package for a semiconductor device according to claim 1, wherein the step includes a continuously formed step.

7. The package for a semiconductor device according to claim 1, wherein the holding resin is also provided on back sides of the lead frames with respect to the major surfaces.

8. The package for a semiconductor device according to claim 1, wherein the holding resin exposed from the gap between the first and second lead frames in the opening of the resin part has a surface including asperities.

9. The package for a semiconductor device according to claim 8, wherein the asperities include projections.

10. The package for a semiconductor device according to claim 8, wherein the asperities include recesses.

11. The package for a semiconductor device according to claim 8, wherein the asperities include at least one groove.

12. The package for a semiconductor device according to claim 1, wherein the resin part is a reflector and the package is a package for an optical semiconductor device.

13. A method of manufacturing a package for a semiconductor device, the method comprising:
a lead frame processing step of forming a step on a side of a lead frame with respect to a major surface;
a die step of placing the lead frame in a die; and
a resin injecting step of injecting resin into the die to form a resin part that opens an element mounting region and holding resin that holds the lead frame,
wherein the step is formed at least on the side of the lead frame exposed from the resin part in an opening of the resin part.

14. The method of manufacturing a package for a semiconductor device according to claim 13, wherein the step is formed by coining.

15. A semiconductor device comprising:
the package for a semiconductor device according to claim 1;
a semiconductor element mounted on the element mounting region;
a conductive material electrically connecting the semiconductor element and the connected region; and
molding resin that molds inside of the opening of the resin part.

16. A semiconductor device comprising:
the package for a semiconductor device according to claim 12;
an optical semiconductor element mounted on the element mounting region;
a conductive material electrically connecting the optical semiconductor element and the connected region; and
translucent resin that molds inside of an opening of the reflector,
wherein the semiconductor device is an optical semiconductor device.
